(19) United States
(12) Patent Application Publication
(10) Pub. No.: US 2019/0103449 A1
(43) Pub. Date: Apr. 4, 2019

(54) ORGANIC LIGHT EMITTING DISPLAY SUBSTRATE AND MANUFACTURE METHOD THEREOF, DISPLAY DEVICE

(71) Applicant: BOE TECHNOLOGY GROUP CO., LTD., Beijing (CN)

(72) Inventor: Wenjun HOU, Beijing (CN)

(73) Assignee: BOE TECHNOLOGY GROUP CO., LTD., Beijing (CN)

(21) Appl. No.: 16/043,878

(22) Filed: Jul. 24, 2018

(30) Foreign Application Priority Data
Sep. 29, 2017 (CN) 201710908938.7

(51) Int. Cl. H01L 27/32; H01L 51/50; H01L 51/00; H01L 51/56

(52) U.S. Cl. CPC H01L 27/3246; H01L 51/5056; H01L 51/56; H01L 51/5072; H01L 51/0005; H01L 51/5092

(57) ABSTRACT

An organic light emitting display substrate and a manufacture method thereof, a display device are provided. The organic light emitting display substrate includes a pixel definition layer, and the pixel definition layer includes a plurality of pixel openings, each of the pixel openings includes a long side portion and a short side portion, and a slope angle of the long side portion is greater than a slope angle of the short side portion.

### CROSS REFERENCE TO RELATED APPLICATION

The present application claims priority to the Chinese patent application No. 201710908938.7, filed on Sep. 29, 2017, the entire disclosure of which is incorporated herein by reference as part of the present application.

### TECHNICAL FIELD

Embodiments of the present disclosure relate to an organic light emitting display substrate and a manufacture method thereof, a display device.

### BACKGROUND

Organic light emitting display devices have advantages such as self-luminescence, fast response, wide viewing angle, high brightness, bright colorful rendering, light weight and thin profile, and so on, and therefore become an important display technology.

At present, an organic light emitting layer of the organic light emitting display device can be formed by inkjet printing, and when the organic light emitting layer is formed by the inkjet printing, a pixel definition layer is required be formed in advance on a base substrate to define a pixel area for ink droplets to be sprayed therein accurately.

### SUMMARY

At least one embodiment of the present disclosure provides an organic light emitting display substrate, the display substrate comprises a pixel definition layer, the pixel definition layer comprises a plurality of pixel openings, each of the pixel openings comprises a long side portion and a short side portion, and a slope angle of the long side portion is greater than a slope angle of the short side portion.

For example, in the organic light emitting display substrate provided by at least one embodiment of the present disclosure, the pixel definition layer comprises a material having a lyophobic property.

For example, in the organic light emitting display substrate provided by at least one embodiment of the present disclosure, the material is a negative photoresist.

For example, the organic light emitting display substrate provided by at least one embodiment of the present disclosure further comprises a base substrate, the pixel definition layer is on a side of the base substrate, and comprises a first pixel definition layer and a second pixel definition layer that are stacked, and the second pixel definition layer is closer to the base substrate than the first pixel definition layer; and the first pixel definition layer comprises the material having the lyophobic property, and the second pixel definition layer comprises a material having a lyophilic property.

For example, in the organic light emitting display substrate provided by at least one embodiment of the present disclosure, each of the pixel openings is in a shape of a rectangle, a parallelogram, a trapezoid, a hexagon or an oval.

At least one embodiment of the present disclosure provides a display device, comprising the above organic light emitting display substrate.

At least one embodiment of the present disclosure provides a manufacture method of the organic light emitting display, comprising: coating a material of the pixel definition layer on a base substrate; forming the long side portion of the pixel definition layer; and forming the short side portion of the pixel definition layer.

For example, in the manufacture method of the organic light emitting display substrate provided by at least one embodiment of the present disclosure, the material of the pixel definition layer is a negative photoresist having a lyophobic property, and the long side portion and the short side portion are formed by an exposure process and a developing process.

For example, in the manufacture method of the organic light emitting display substrate provided by at least one embodiment of the present disclosure, the long side portion and the short side portion are exposed respectively by two exposure processes.

For example, in the manufacture method of the organic light emitting display substrate provided by at least one embodiment of the present disclosure, an exposure amount along the long side portion is smaller than an exposure amount along the short side portion.

For example, in the manufacture method of the organic light emitting display substrate provided by at least one embodiment of the present disclosure, the long side portion and the short side portion are exposed simultaneously by one exposure process through a gray tone mask or a halftone mask.

For example, in the manufacture method of the organic light emitting display substrate provided by at least one embodiment of the present disclosure, coating of the material of the pixel definition layer on the base substrate comprises: coating of a material of a second pixel definition layer on a side of the base substrate and then coating of a material of a first pixel definition layer on the second pixel definition layer, wherein the material of the first pixel definition layer comprises the material having the lyophobic property, and the material of the second pixel definition layer comprises a material having a lyophilic property.

For example, the manufacture method of the organic light emitting display substrate provided by at least one embodiment of the present disclosure further comprises: inkjet printing an organic material in the openings of the pixel definition layer to form an organic functional layer.

For example, in the manufacture method of the organic light emitting display substrate provided by at least one embodiment of the present disclosure, the organic functional layer comprises one or more of a light emitting layer, an electron injection layer, a hole injection layer, an electron transport layer, and a hole transport layer.

### BRIEF DESCRIPTION OF THE DRAWINGS

In order to clearly illustrate the technical solution of the embodiments of the disclosure, the drawings of the embodiments will be briefly described in the following; it is obvious that the described drawings are only related to some embodiments of the disclosure and thus are not limitative of the disclosure.

FIG. 1 is a plan view of a pixel definition layer in an organic light emitting display substrate provided by an embodiment of the present disclosure;

FIG. 2 is a sectional view of a pixel definition layer in an organic light emitting display substrate provided by an embodiment of the present disclosure;

FIG. 3 is another sectional view of a pixel definition layer in an organic light emitting display substrate provided by an embodiment of the present disclosure;

FIG. 4 is a sectional view of another pixel definition layer in an organic light emitting display substrate provided by an embodiment of the present disclosure;

FIGS. 5A-5D are schematic diagrams of shapes of openings in a pixel definition layer in an organic light emitting display substrate provided by an embodiment of the present disclosure;

FIG. 6 is a schematic diagram of an organic light emitting display substrate provided by an embodiment of the present disclosure;

FIG. 7 is a flow diagram of a manufacture method of an organic light emitting display substrate provided by an embodiment of the present disclosure;

FIGS. 8A-8C are schematic diagrams of an organic light emitting display substrate in a manufacture process provided by an embodiment of the present disclosure;

FIG. 9 is a schematic diagram of a mask provided by an embodiment of the present disclosure; and

FIGS. 10A-10B are schematic diagrams of another organic light emitting display substrate in a manufacture process provided by an embodiment of the present disclosure.

### DETAILED DESCRIPTION

In order to make objects, technical details and advantages of the embodiments of the disclosure apparent, the technical solutions of the embodiments will be described in a clearly and fully understandable way in connection with the drawings related to the embodiments of the disclosure. Apparently, the described embodiments are just a part but not all of the embodiments of the disclosure. Based on the described embodiments herein, those skilled in the art can obtain other embodiment(s), without any inventive work, which should be within the scope of the disclosure.

Unless otherwise defined, all the technical and scientific terms used herein have the same meanings as commonly understood by one of ordinary skill in the art to which the present disclosure belongs. The terms “first,” “second,” etc., which are used in the description and the claims of the present application for disclosure, are not intended to indicate any sequence, amount or importance, but distinguish various components. Also, the terms such as “a,” “an,” etc., are not intended to limit the amount, but indicate the existence of at least one. The terms “comprise,” “comprising,” “include,” “including,” etc., are intended to specify that the elements or the objects stated before these terms encompass the elements or the objects and equivalents thereof listed after these terms, but do not preclude the other elements or objects. The phrases “connect”, “connected”, etc., are not intended to define a physical connection or mechanical connection, but may include an electrical connection, directly or indirectly. “On,” “under,” “right,” “left” and the like are only used to indicate relative position relationship, and when the position of the object which is described is changed, the relative position relationship may be changed accordingly.

When an organic light emitting layer of an organic light emitting display is formed by an inkjet printing method, a pixel definition layer is required be formed in advance on a base substrate to define a pixel area for the ink droplets to be sprayed therein accurately. Generally, the pixel definition layer comprises a plurality of openings, and in an inkjet printing process, ink applied by the inkjet printing may diffuse ununiformly in the opening, which causes the morphology of the organic light emitting layer formed at different positions of the opening to be ununiform, and therefore causes the brightness of the pixel area of the display device to be ununiform when the pixel area emits light, which seriously affects the display effect of the organic light emitting display device.

For example, the plurality of openings of the pixel definition layer are generally in a certain shape, in the inkjet printing process, when the ink of the inkjet printing is sprayed in the opening of the certain shape, the ink diffuses from a middle position of the opening to a peripheral position of the opening. Because the opening of the pixel definition layer is generally in an irregular shape, the diffusion of the ink in different directions may be affected differently. For example, in the case where the opening of the pixel definition layer is in a shape of a rectangular, the distance from the middle position of the opening to each boundary of the opening is different, and therefore the diffusion of the ink in different directions are generally ununiform.

At least one embodiment of the present disclosure provides an organic light emitting display substrate, the display substrate comprises a pixel definition layer, the pixel definition layer comprises a plurality of pixel openings, each of the pixel openings comprises a long side portion and a short side portion, and a slope angle of the long side portion is greater than a slope angle of the short side portion.

At least one embodiment of the present disclosure provides a display device, comprising the above organic light emitting display substrate.

At least one embodiment of the present disclosure provides a manufacture method of the above organic light emitting display substrate, comprising: coating a material of the pixel definition layer on a base substrate; forming the long side portion of the pixel definition layer; and forming the short side portion of the pixel definition layer.

The organic light emitting display substrate and the manufacture method thereof, the display device of the present disclosure are described below through several specific embodiments.

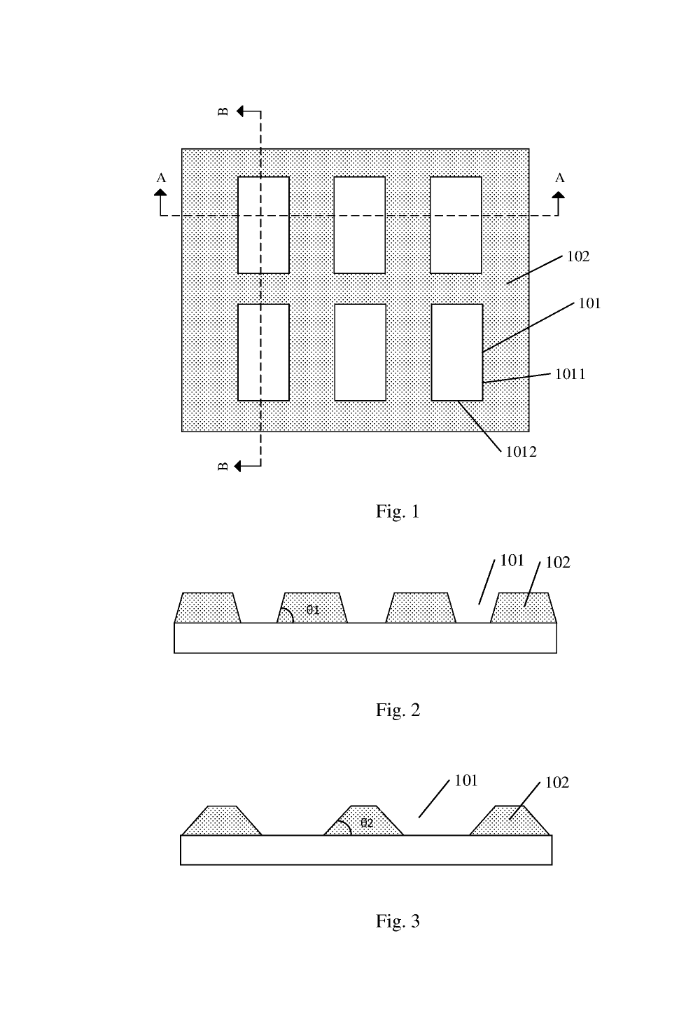

At least one embodiment of the present disclosure provides an organic light emitting display substrate, the display substrate comprises a pixel definition layer, and FIG. 1 is a plan view of the pixel definition layer in the organic light emitting display substrate provided by the embodiment, and FIG. 2 and FIG. 3 are sectional views of the pixel definition layer in directions of line AA and line BB in FIG. 1, respectively.

As illustrated in FIGS. 1-3, the pixel definition layer 102 comprises a plurality of pixel openings 101; each of the pixel openings 101 comprises a long side portion 1011 and a short side portion 1012, and a slope angle of the long side portion 1011 is larger than a slope angle of the short side portion 1012.

For example, the sectional view of the pixel definition layer 102 along the direction of line AA illustrated in FIG. 2 shows the slope angle θ1 of the long side portion 1011 of the pixel opening 101; and the sectional view of the pixel definition layer 102 along the direction of line BB illustrated in FIG. 3 shows the slope angle θ2 of the short side portion 1012 of the pixel opening 101. The slope angle θ1 is larger than the slope angle θ2.

For example, the angle value of 01 may be 45°-70°, for example, 50°, 60°, 70° or the like; and the angle value of θ2 may be 30°-50°, for example, when θ1 is 50°, θ2 may be 30°; when θ1 is 60°, θ2 may be 40°; when θ1 is 70°, θ2 may be 50° or the like.

In the embodiment, the specific exemplary angle values of the slope angles θ1 and θ2 can be determined, for example, according to specific lengths of the long side portion 1011 and the short side portion 1012 and the difference between the lengths of the long side portion 1011 and the short side portion 1012. For example, in the case where the difference between the lengths of the long side portion 1011 and the short side portion 1012 is large, the difference between the slope angle values of the long side portion 1011 and the short side portion 1012 can also be large. In addition, the angle values of the slope angles θ1 and θ2 can be determined, for example, according to actual situations such as the material of the pixel definition layer and properties (for example, surface tension) of the ink of the inkjet printing in the pixel definition layer, and the embodiment does not limit specific angle values of the slope angles θ1 and θ2.

In the embodiment, the pixel definition layer 102 can comprise, for example, a material having a lyophobic property, and for example is formed of the material having the lyophobic property. For example, the material having the lyophobic property comprised in the pixel definition layer 102 is a material of which a surface is difficult to be wetted by the ink that is inkjet printed on the surface of the material. Because the material having the lyophobic property is difficult to be wetted by the ink, the climbing resistance against the ink on side walls (for example, the long side portion and the short side portion) of the pixel opening 101 can be increased in the case where the material is used for preparing the pixel definition layer 102, and therefore the climbing speed of the ink on the side walls of the pixel opening 101 is slowed down, and the ink is prevented from overflowing into an adjacent pixel opening 101.

In the embodiment, the material having the lyophobic property can be, for example, a photoresist having the lyophobic property, and the photoresist can be, for example, a negative photoresist having the lyophobic property such as polyimide (PI), polymethyl methacrylate (PMMA), silicone or the like. Of course, the photoresist can also be a positive photoresist. The specific type of the photoresist is not limited in the embodiment. If the pixel definition layer is prepared by a photoresist having the lyophobic property, the preparation process of the pixel definition layer can be simplified. For example, an exposure process and a development process can be used to form a patterned pixel definition layer without performing other additional processes such as etching and so on.

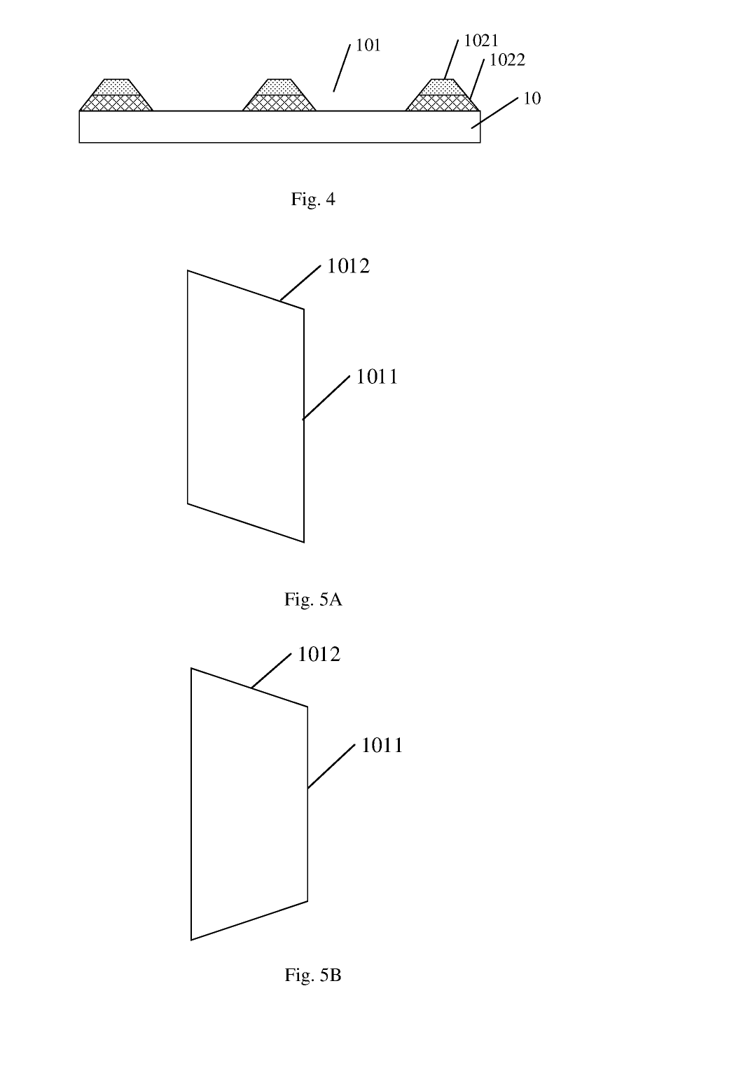

In another example of the embodiment, as illustrated in FIG. 4, the pixel definition layer can comprise, for example, a first pixel definition layer 1021 and a second pixel definition layer 1022 that are stacked on the base substrate 10 from bottom to up, and the second pixel definition layer 1022 is closer to a base substrate 10 than the first pixel definition layer 1021. The first pixel definition layer 1021 can comprise, for example, a material having a lyophobic property or formed of the material having the lyophobic property, and the second pixel definition layer 1022 can comprise, for example, a material having a lyophilic property or formed of the material having the lyophilic property. In the embodiment, the material having the lyophilic property is, for example, a material of which a surface is easily wetted by the ink that is inkjet printed later. Because the material having the lyophilic property can be easily wetted by the ink, the material can adsorb the ink, so when the ink is inkjet printed in the pixel definition layer comprising the material having the lyophilic property, the adsorption can bring the ink closer to the direction in which the base substrate is placed during the period that the ink is becoming a film, and therefore the ink is prevented from climbing on the side walls of the pixel definition layer, and non-uniformity of the film formed in the pixel opening caused by the climbing of the ink is reduced. Therefore, in the case where the material having the lyophilic property is used for preparing a bottom layer of the pixel definition layer, the ink can be easily spread out at the bottom of the pixel opening 101 to make the distribution of the ink in the pixel opening 101 more uniform; and the first pixel definition layer 1021 that is in the upper layer is prepared by the material having the lyophobic property to increase the climbing resistance against the ink on the upper portion of the side walls of the pixel opening 101, and therefore the climbing speed of the ink on the upper portion of the side walls of the pixel opening 101 is slowed down, and the ink is prevented from overflowing into an adjacent pixel opening 101.

In the embodiment, the pixel opening 101 can be substantially in a shape of a rectangular or another suitable shape, for example, a shape having sides of different lengths in different directions, for example, a modified shape of a rectangle or the like. For example, the pixel opening 101 can be in a shape of a parallelogram as illustrated in FIG. 5A, the relatively longer and parallel two sides of the parallelogram correspond to the long side portion 1011 of the pixel opening 101, and the relatively shorter and parallel two sides correspond to the short side portion 1012 of the pixel opening 101. The pixel opening 101 can be, for example, in a shape of a trapezoid as illustrated in FIG. 5B. For example, the relatively longer and parallel two bottom sides of the trapezoid correspond to the long side portion 1011 of the pixel opening 101, and the other two sides correspond to the short side portion 1012 of the pixel opening 101. The pixel opening 101 can be, for example, in a shape of a hexagon as illustrated in FIG. 5C, for example, the relatively longer and parallel two sides of the hexagon correspond to the long side portion 1011 of the pixel opening 101, and the relatively shorter four sides correspond to the short side portion 1012 of the pixel opening 101. The pixel opening 101 can also be, for example, in a shape of an oval or a modifying shape of an oval. For example, the pixel opening 101 is in a shape of a racetrack as illustrated in FIG. 5D. For example, two parallel straight sides of the racetrack correspond to the long side portion 1011 of the pixel opening 101, and two arc sides correspond to the short side portion 1012 of the pixel opening 101. The shape of the pixel opening 101 is not limited in the embodiment as long as the pixel opening comprises sides of different lengths in different directions.

In the embodiment, in a first aspect, because the pixel opening comprises sides of different lengths in different directions, after the ink is inkjet printed in the pixel opening, the amount of ink diffusing to reach the side of the pixel opening in each direction per unit of time is different. For example, when the pixel opening is in a shape of a rectangular, compared with the short side direction, the ink diffuses in the long side direction for a longer distance, so that it takes a longer time period for the ink to diffuse along the long side direction to reach the short side, that is, the amount of ink reaching the short side per unit of time is small. In a second aspect, the long side portion of the pixel opening of the pixel definition layer in the organic light emitting display substrate provided by the embodiment has a large slope angle, so that the ink that is inkjet printed in the opening is difficult to climb on the long side portion. Therefore, the long side portion having the large slope angle generates a large resistance against the diffusion of the ink dropped into the pixel opening, and the ink tends to diffuse in the long side direction. In addition, the short side portion of the pixel opening has a smaller slope angle, which makes the ink easier to climb on the short side portion, so the short side portion has a less resistance against the ink diffusion, which further allows the ink to easily diffuse in the long side direction to reach the boundary of the short side portion. That is, the pixel definition layer provided by the embodiment can speed up the diffusion of ink along the long side portion. Combined with the first aspect, the pixel definition layer in the organic light emitting display substrate provided by the embodiment can allow the amount of ink reaching each side boundary per unit of time to be more uniform, for example, the same, and therefore allow the distribution of the ink in the pixel opening to be more uniform, and allow the pattern (for example, thickness and surface morphology) of the ink to be more uniform after drying.

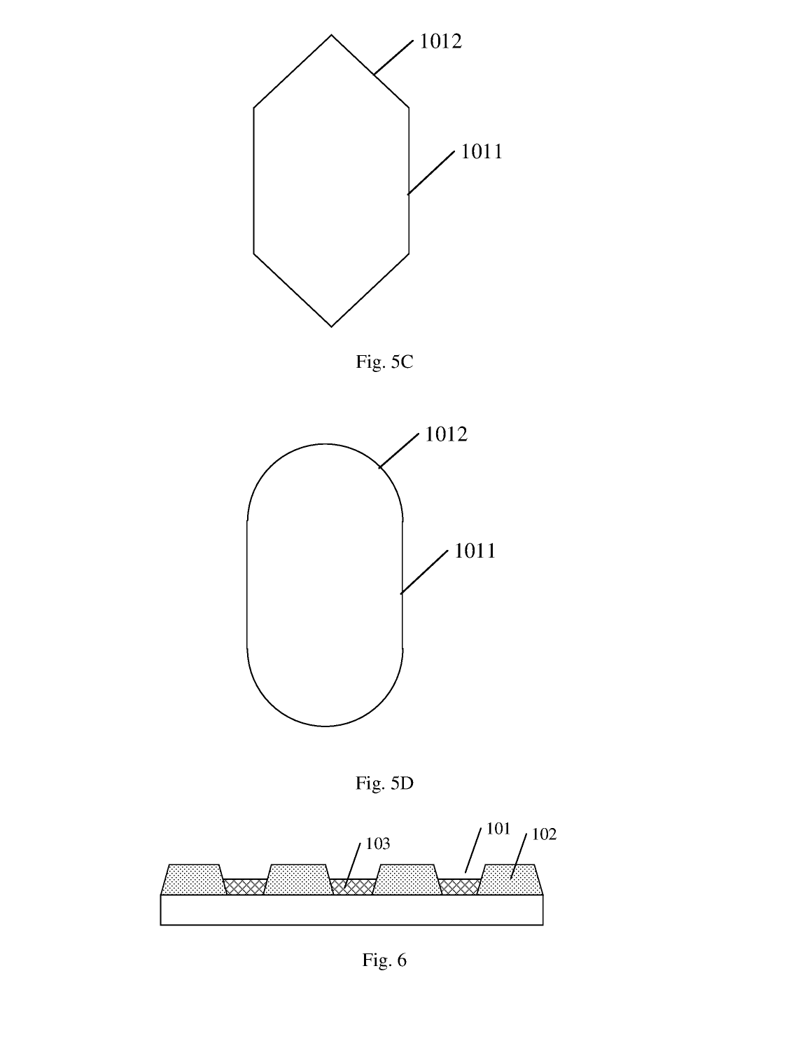

For example, as illustrated in FIG. 6, the organic light emitting display substrate provided by at least one embodiment of the present disclosure comprises a plurality of pixels, and each pixel corresponds to the pixel opening 101 of the pixel definition layer 102.

In the embodiment, an organic functional layer 103 of the organic light emitting display substrate can be formed, for example, by inkjet printing an organic material in each pixel opening 101 of the pixel definition layer 102. The pixel definition layer 102 can render the pattern of the organic functional layer 103 formed by inkjet printing to be more uniform, for example, render the thickness of the organic functional layer 103 to be more uniform, and render non-uniform ranges (for example, the ununiform morphology, the ununiform width, and so on) of the organic functional layer 103 generated at different side boundaries of the pixel opening are substantially the same, and therefore the light brightness of the display substrate is more uniform during operation of display, and the display uniformity of the display substrate are improved.

In the embodiment, the organic functional layer 103 can comprise, for example, a light emitting layer, an electron injection layer, a hole injection layer, an electron transport layer, a hole transport layer and so on, which is not limited in the embodiment.

In the embodiment, the organic light emitting display substrate can further comprise other functional structures such as a pixel driving circuit, an anode layer, a cathode layer, a planarization insulating layer and so on, which are not described in the embodiment for the purpose of simplicity.

At least one embodiment of the present disclosure further provides a display device, and the display device comprises the above organic light emitting display substrate. The display device can be, for example, any product or component having a function of display such as an organic light emitting display panel, a mobile phone, a tablet computer, a television, a display, a notebook computer, a digital photo frame, a navigator, and so on, which is not limited in the embodiment.

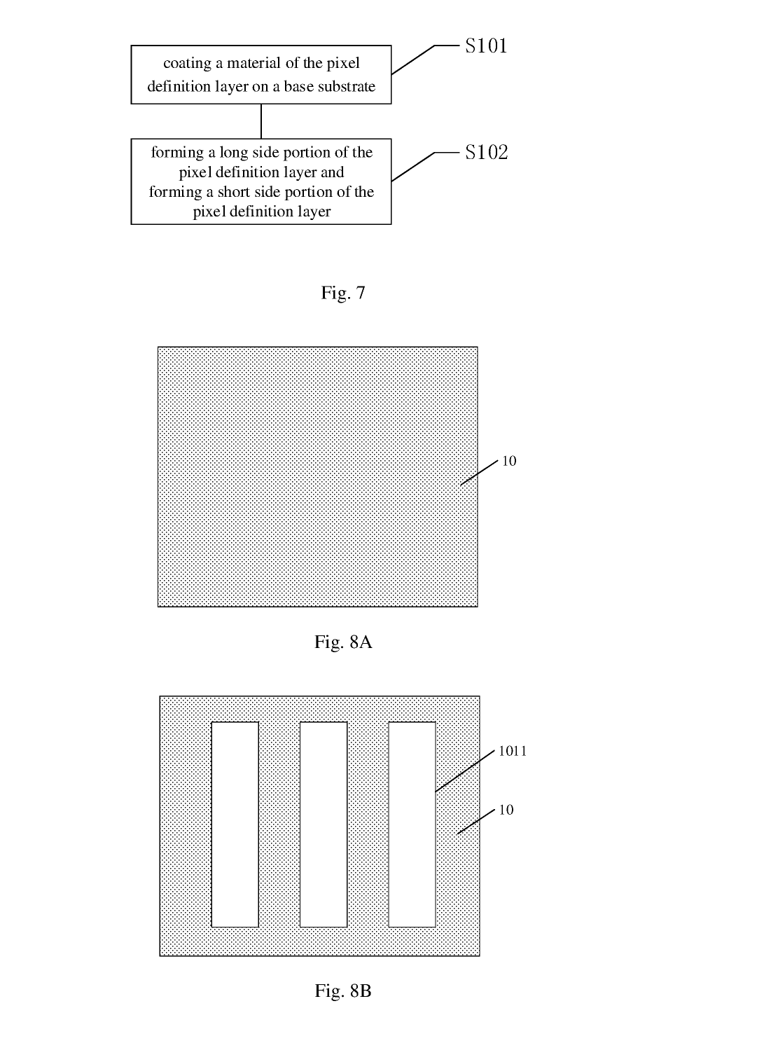

At least one embodiment of the present disclosure provides a manufacture method of the above organic light emitting display substrate. As illustrated in FIG. 7, the method comprises steps S101 to S102.

Step S101: coating a material of the pixel definition layer on a base substrate.

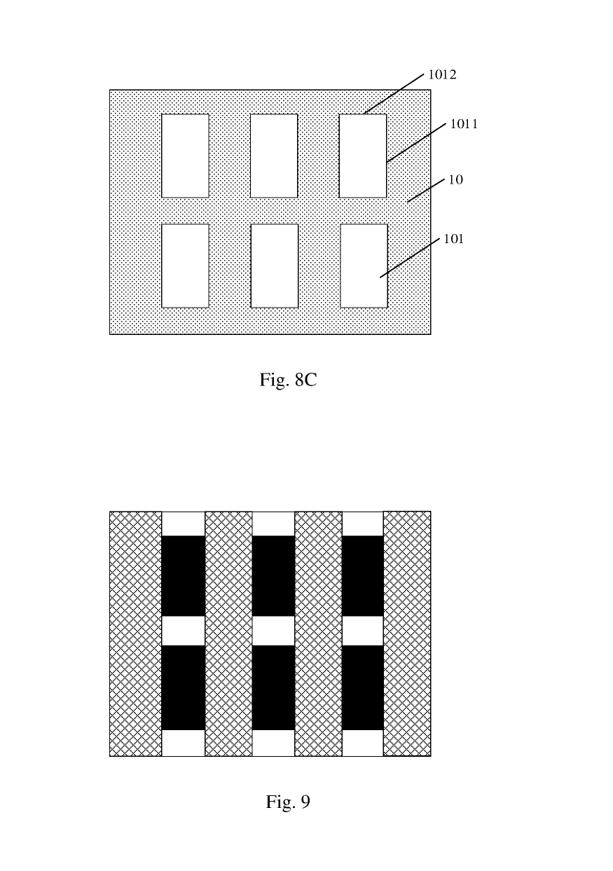

In the embodiment, as illustrated in FIG. 8A, the material of the pixel definition layer is first coated on a base substrate 10. The material of the pixel definition layer can comprise, for example, a material having a lyophobic property. The material can be, for example, a negative photoresist having the lyophobic property, such as a negative photoresist such as polyimide (PI), polymethyl methacrylate (PMMA), silicone or the like.

In the embodiment, the material having the lyophobic property adopted in the pixel definition layer is difficult to be wetted by the ink used in an inkjet printing process, so the diffusion resistance against the ink inkjet printed later in the pixel opening can be increased in the case where the material is used for preparing the pixel definition layer, and therefore the climbing speed of the ink on side walls of the pixel opening is slowed down, and the ink is prevented from overflowing into an adjacent pixel opening.

Step S102: forming a long side portion of the pixel definition layer and forming a short side portion of the pixel definition layer.

In the embodiment, when the material of the pixel definition layer comprises the negative photoresist having the lyophobic property, the long side portion and the short side portion can be formed by an exposure process and a developing process.

In the embodiment, for example, the material of the pixel definition layer can be exposed by two exposure processes to form the long side portion and the short side portion respectively. In an example, as illustrated in FIG. 8B, the material of the pixel definition layer in the example comprises the negative photoresist having the lyophobic property, such as polyimide (PI), polymethyl methacrylate (PMMA), silicone or other suitable materials. In the example, for example, the long side portion 1011 of the pixel definition layer can be formed first. As illustrated in FIG. 8B, for example, the shadow region except for regions corresponding to positions at which at least pixel openings will be formed in the pixel definition layer in FIG. 8B is exposed through a mask, so the material of the pixel definition layer in the exposed region is not dissolved in a subsequent development process.

In the embodiment, after the long side portion 1011 of the pixel definition layer is exposed, the short side portion is exposed. As illustrated in FIG. 8C, for example, regions corresponding to at least interval areas (or isolation areas) of the short side portions 1012 of the pixel openings in FIG. 8C can be exposed, so that the material of the pixel definition layer in the exposed region is not dissolved in the subsequent development process.

In the embodiment, when the material of the pixel definition layer comprises the negative photoresist having the lyophobic property, the exposure amount along the long side portion 1011 can be, for example, smaller than the exposure amount along the short side portion 1012 when performing the exposure process, and therefore the slope angle of the long side portion 1011 of the pixel opening in the pixel definition layer can be formed larger than the slope angle of the short side portion 1012. In the embodiment, the values of the slope angles of the long side portion 1011 and the short side portion 1012 can be adjusted, for example, by adjusting the exposure amounts to the long side portion 1011 and the short side portion 1012 in the exposure process. For example, the smaller the exposure amount to the long side portion 1011 or the short side portion 1012, the larger the slope angle formed.

In the embodiment, for example, the development process can be performed after the long side portion 1011 and the short side portion 1012 is exposed to dissolve the material of the pixel definition layer that is unexposed in the area for forming the pixel opening (the exposed material is not dissolved), and therefore the pixel opening 101 is formed.

In the embodiment, of course, the short side portion 1012 of the pixel definition layer can be exposed first, and then the long side portion 1011 is exposed. In the embodiment, an exposure order of the long side portion 1011 and the short side portion 1012 is not limited and can be changed if required.

In another example of the embodiment, for example, the long side portion 1011 and the short side portion 1012 may be simultaneously exposed by one exposure process using a gray tone mask or a halftone mask, and then the development process can be performed to form a pixel opening 101 comprising the long side portion 1011 and the short side portion 1012. The exposure pattern of the gray tone mask or the halftone mask can allow the exposure amounts of the long side portion and the short side portion of the pixel opening of the pixel definition layer to be different from each other.

For example, FIG. 9 illustrates a mask provided by the embodiment, a position of the mask corresponding to the pixel opening of the pixel definition layer is opaque (the black portion in the figure), and a position of the mask corresponding to the long side portion of the pixel opening is partially transparent (e.g., semi-transmissive) (the shaded portion in the figure), and a position of the mask corresponding to the short side portion of the pixel opening is completely transparent (the white portion in the figure), and therefore the exposure amount to the long side portion can be less than the exposure amount to the short side portion in the exposure process, and the slope angle of the long side portion in the pixel opening can be formed larger than the slope angle of the short side portion. In the embodiment, the partial transparent degree of the position of the mask corresponding to the long side portion of the pixel opening can be adjusted according to an actual situation such as the slope angle of the long side portion, which is not limited in the embodiment.

In one example of the embodiment, the pixel definition layer comprises a first pixel definition layer 1021 and a second pixel definition layer 1022 that are stacked, and the second pixel definition layer 1022 is closer to a base substrate 10 than the first pixel definition layer 1021, as illustrated in FIG. 4; the first pixel definition layer can comprise, for example, a material having a lyophobic property, and the second pixel definition layer can comprise, for example, a material having a lyophilic property. For example, the material having the lyophobic property comprised in the first pixel definition layer and the material having the lyophilic property comprised in the second pixel definition layer are both negative photoresists; in a manufacture process of the pixel definition layer, for example, the material of the second pixel definition layer and the material of the first pixel definition layer can be sequentially coated on the base substrate, and then an exposure process and a development process are performed on the material of the second pixel definition layer and the material of the first pixel definition layer material simultaneously to form the pixel openings. Alternatively, in another manufacture process of the pixel definition layer, for example, the material of the second pixel definition layer is coated on the base substrate first, and an exposure process and a developing process are performed to form a second pixel definition layer, and then the material of the first pixel definition layer is coated on the second pixel definition layer, and another exposure process and another development process are further performed to form the first pixel definition layer. That is, the first pixel definition layer and the second pixel definition layer can be formed separately by different exposure processes and different development processes. In the example, the specific manufacture process of the pixel definition layer can be selected according to an actual situation such as material properties of the pixel definition layer, which is not limited in the embodiment.

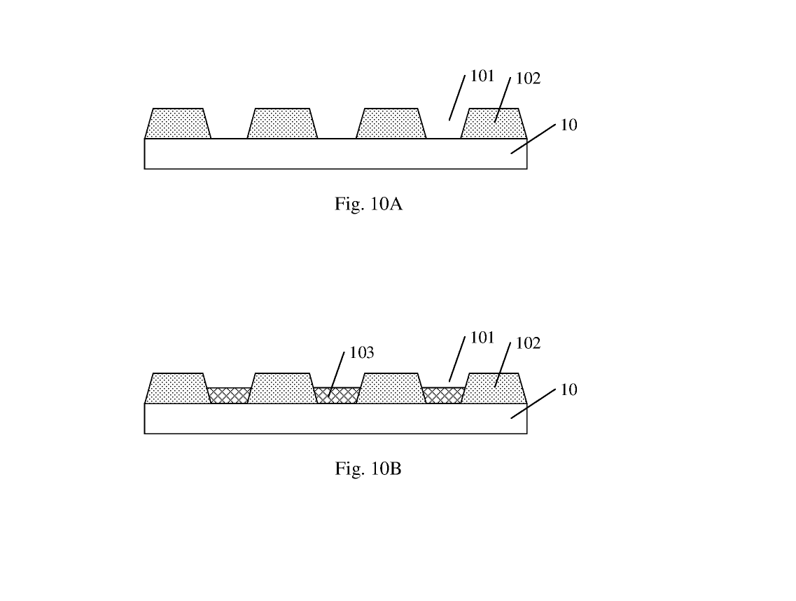

For example, as illustrated in FIGS. 10A and 10B, the manufacture method of the organic light emitting display substrate provided by at least one embodiment of the present disclosure further comprises: forming a pixel structure in each of the pixel openings 101 of the pixel definition layer 102.

In the embodiment, forming the pixel structure in each pixel opening 101 of the pixel definition layer 102 can comprise, for example, inkjet printing an organic material in the pixel opening 101 of the pixel definition layer 102 to form an organic functional layer 103. The organic functional layer 103 can be, for example, one or more of a light emitting layer, an electron injection layer, a hole injection layer, an electron transport layer, and a hole transport layer, which is not limited in the embodiment.

In the embodiment, the manufacture method of the organic light emitting display substrate can further comprise the steps of forming other functional structures such as a pixel driving circuit, an anode layer, a cathode layer, a planarization insulating layer and so on, which are not described in the embodiment.

In the organic light emitting display substrate manufactured by the method of the embodiment, the pattern of the organic functional layer 103 is more uniform, for example, the thickness of the organic functional layer 103 is more uniform, and non-uniform degrees (for example, the ununiform morphology, the ununiform width, and the like) of the organic functional layer 103 which are generated at different boundaries of the pixel opening are substantially the same, and therefore the light brightness of the display substrate is more uniform during operation of display, and the display uniformity of the display substrate is better, that is, the display effect is better.

The following statements should be noted:

(1) The accompanying drawings involve only the structure(s) in connection with the embodiment(s) of the present disclosure, and other structure(s) can be referred to common design(s).

(2) For the purpose of clarity only, in accompanying drawings for illustrating the embodiment(s) of the present disclosure, the thickness of a layer or a structure may be enlarged or reduced. However, it should understood that, in the case in which a component or element such as a layer, film, area, substrate or the like is referred to be “on” or “under” another component or element, it may be directly on or under the another component or element or a component or element is interposed therebetween.

(3) In case of no conflict, features in one embodiment or in different embodiments can be combined.

What are described above is related to the illustrative embodiments of the disclosure only and not limitative to the scope of the disclosure; the scopes of the disclosure are defined by the accompanying claims.

What is claimed is:

1. An organic light emitting display substrate, comprising a pixel definition layer, wherein the pixel definition layer comprises a plurality of pixel openings,
each of the pixel openings comprises a long side portion and a short side portion, and a slope angle of the long side portion is greater than a slope angle of the short side portion.

2. The organic light emitting display substrate according to claim 1, wherein the pixel definition layer comprises a material having a lyophobic property.

3. The organic light emitting display substrate according to claim 2, wherein the material is a negative photoresist.

4. The organic light emitting display substrate according to claim 1, further comprising a base substrate,
wherein the pixel definition layer is on a side of the base substrate, and comprises a first pixel definition layer and a second pixel definition layer that are stacked, and the second pixel definition layer is closer to the base substrate than the first pixel definition layer; and
the first pixel definition layer comprises the material having the lyophobic property, and the second pixel definition layer comprises a material having a lyophilic property.

5. The organic light emitting display substrate according to claim 1, wherein each of the pixel openings is in a shape of a rectangle, a parallelogram, a trapezoid, a hexagon or an oval.

6. A display device, comprising the organic light emitting display substrate according to claim 1.

7. A manufacture method of the organic light emitting display substrate according to claim 1, comprising:
coating a material of the pixel definition layer on a base substrate;
forming the long side portion of the pixel definition layer; and
forming the short side portion of the pixel definition layer.

8. The manufacture method of the organic light emitting display substrate according to claim 7,
wherein the material of the pixel definition layer is a negative photoresist having a lyophobic property, and the long side portion and the short side portion are formed by an exposure process and a developing process.

9. The manufacture method of the organic light emitting display substrate according to claim 8, wherein the long side portion and the short side portion are exposed respectively by two exposure processes.

10. The manufacture method of the organic light emitting display substrate according to claim 9,
wherein an exposure amount along the long side portion is smaller than an exposure amount along the short side portion.

11. The manufacture method of the organic light emitting display substrate according to claim 8,
wherein the long side portion and the short side portion are exposed simultaneously by one exposure process through a gray tone mask or a halftone mask.

12. The manufacture method of the organic light emitting display substrate according to claim 7, wherein coating of the material of the pixel definition layer on the base substrate comprises:
coating of a material of a second pixel definition layer on a side of the base substrate and then coating of a material of a first pixel definition layer on the second pixel definition layer,
wherein the material of the first pixel definition layer comprises the material having the lyophobic property, and the material of the second pixel definition layer comprises a material having a lyophilic property.

13. The manufacture method of the organic light emitting display substrate according to claim 7, further comprising:
inkjet printing an organic material in the openings of the pixel definition layer to form an organic functional layer.

14. The manufacture method of the organic light emitting display substrate according to claim 8,
wherein the organic functional layer comprises one or more of a light emitting layer, an electron injection layer, a hole injection layer, an electron transport layer, and a hole transport layer.
